(19) United States
(12) Patent Application Publication
(10) Pub. No.: US 2025/0258515 A1
(43) Pub. Date: Aug. 14, 2025

(54) CONTROL SYSTEM AND METHOD

(71) Applicant: Cypress Semiconductor Corporation, San Jose, CA (US)

(72) Inventors: Bert Sullam, Bellevue, WA (US); Eashwar Thiagarajan, Bothell, WA (US); Ketan Dewan, Fremont, CA (US); Ashish Kumar Reddy Somagatta, Bellevue, WA (US)

(73) Assignee: CYPRESS SEMICONDUCTOR CORPORATION, San Jose, CA (US)

(21) Appl. No.: 18/441,188

(22) Filed: Feb. 14, 2024

(51) Int. Cl. G06F 1/02; G06F 1/03; H03K 17/0814

(52) U.S. Cl. CPC G06F 1/022; G06F 1/0328; H03K 17/08142

(57) ABSTRACT

According to some embodiments, a system comprises a memory configured to store protection waveform data, and a comparator waveform generator configured to access the memory to generate a protection waveform from the protection waveform data based on a trigger associated with the system, receive a measured system characteristic waveform, and generate a fault interrupt responsive to a comparison between the measured system characteristic waveform and the protection waveform violating a fault condition.

### BACKGROUND

Industrial control systems employ power switching technology for various applications, such as motor control, power factor control, voltage regulation, voltage conversion, power supply, and other application. Protection circuits in the industrial control system protect the system from various faults, such as overcurrent faults, overvoltage faults, or other faults.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a system comprises a memory configured to store protection waveform data, and a comparator waveform generator configured to access the memory to generate a protection waveform from the protection waveform data based on a trigger associated with the system, receive a measured system characteristic waveform, and generate a fault interrupt responsive to a comparison between the measured system characteristic waveform and the protection waveform violating a fault condition.

According to some embodiments, an industrial controller comprises a controller implemented by a microcontroller and configured to control an industrial process, a memory configured to store protection waveform data, and a comparator waveform generator configured to access the memory based on a set of access parameters to generate a protection waveform based on the protection waveform data and a trigger event, receive a measured system characteristic waveform associated with an industrial system controlled by the controller and associated with the industrial process, and generate a fault interrupt for the microcontroller responsive to a comparison between the measured system characteristic waveform and the protection waveform violating a fault condition.

According to some embodiments, a system comprises means for receiving a trigger associated with an industrial control system, means for accessing a memory storing protection waveform data based on a set of access parameters to generate a protection waveform based on the protection waveform data and the trigger, means for receiving a measured system characteristic waveform associated with the industrial control system, and means for generating a fault interrupt responsive to a comparison between the measured system characteristic waveform and the protection waveform violating a fault condition.

According to some embodiments, a method comprises receiving a trigger associated with an industrial control system, accessing a memory storing protection waveform data based on a set of access parameters to generate a protection waveform based on the protection waveform data and the trigger, receiving a measured system characteristic waveform associated with the industrial control system, and generating a fault interrupt responsive to a comparison between the measured system characteristic waveform and the protection waveform violating a fault condition.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a schematic diagrams of a motor system, according to some embodiments.

FIG. 2 is a diagram illustrating example protection waveforms that may be stored in a protection waveform memory, according to some embodiments.

FIG. 3 is a diagram of a comparator waveform generator employing a protection waveform memory, according to some embodiments.

FIG. 4 is a diagram illustrating multiple comparator waveform generators with a shared protection waveform memory, according to some embodiments.

FIG. 5 is a simplified flow diagram of a method for implementing industrial control protection, according to some embodiments.

FIG. 6 illustrates an exemplary computer-readable medium, according to some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

Industrial control systems employ power switching technology for various applications, such as motor control, power factor control, voltage regulation, voltage conversion, power supply, and other application. These systems may employ pulse width modulation (PWM) techniques in the industrial control system. Field-Oriented Control (FOC) is a method of variable speed control using PWM signals for three-phase alternating current (AC) electric motors to improve power efficiency with fast control response over a full range of motor speeds. The techniques and devices discussed may be applied to other motor designs, control structures, and the like (e.g., single-phase and three-phase variable frequency drives, digital phase converters, three-phase and single-phase motors, direct torque control drives, induction motors, regenerative drives, brushless DC motors, etc.), and remain within the scope of the disclosure.

Power factor controllers monitor current and voltage to determine the power factor of a system, representing the ratio between real power delivered to a load and reactive power that cycles in the system without accomplishing actual work. A power factor controller may use a switching regulator controlled by a PWM signal to shape the power characteristics of the system to increase the power factor and reduce harmonics. Low power factors pose a difficulty for a power grid by increasing heating losses and potentially causing power failures.

Regulated power supplies or voltage regulators are employed to provide the voltage and current supply to microelectronic devices. Switching power converters (SPC) provide high efficiency, high current capability, and topology flexibility. Switching regulators use PWM signals to provide precise voltage and current characteristics required by devices such as microprocessors, microcontrollers, memory devices, and the like.

According to some embodiments, a protection system is provided that employs a protection waveform memory to allow real-time generation of time varying protection waveforms for protection circuits in industrial control systems. The protection waveform generated by the protection waveform memory can be compared to measured characteristics of the operating industrial control system using a fast comparator to identify fault conditions and implement protective actions without intervention from a host processor of the industrial system. A comparator waveform generator performs the protection function and operates independently from the host processor. The comparator waveform generator may be programmed during system startup to define the addressing parameters used for the protection waveform memory to generate the protection waveform, such as start address, end address, step size, step direction, or update period (e.g., programmable time between successive waveform steps). The comparator waveform generator may perform protection operations responsive to multiple trigger events, where each trigger event has a different set of addressing parameters for the protection waveform memory. For example, a first protection waveform may be used for startup, a second protection waveform may be used during run time operation, and a third protection waveform may be used during shutdown. The comparator waveform generator may generate a direct hardware protection operation or send an interrupt to the host processer to take a protective action when the measured characteristics of the industrial system (e.g., motor current, load current, etc.) deviate from the protection waveform, such as to shut down the PWM signal generator to reduce the current.

In some embodiments, multiple comparator waveform generators may share a single protection waveform memory. For example, comparator waveform generators may be provided for each phase of a motor. The comparator waveform generators may access the protection waveform memory using different starting address (e.g., at the first entry for phase U, the entry one third through the protection waveform memory entries for phase V, and the entry two thirds through the protection waveform memory entries for phase W). In this manner the same waveform can be used for all three phases, where the phase shift is defined by the staring address. A similar approach may be used for a power factor controller or for each phase of a multiphase power converter.

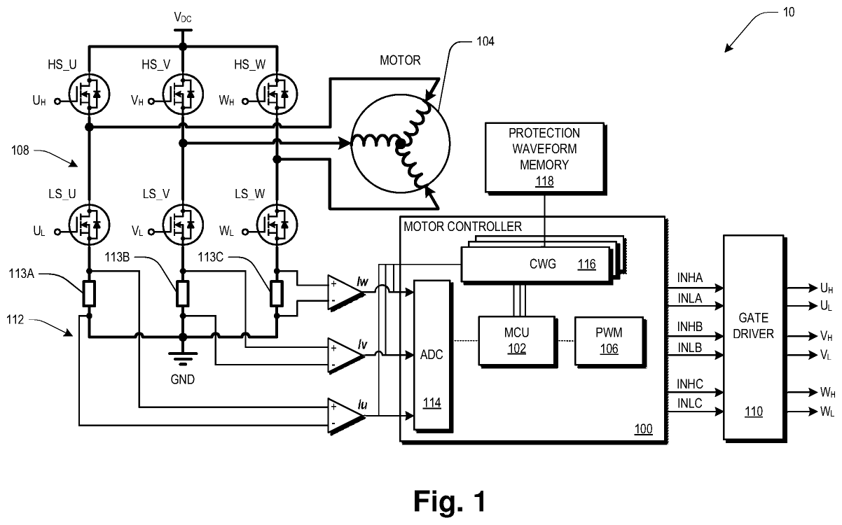

FIG. 1 is a schematic diagram of a motor system 10, according to some embodiments. The motor system 10 is used to illustrate the protection techniques of the present disclosure, however, these protection techniques may be applied to other industrial control systems, such as power factor controllers measuring AC current and AC voltage, or power converters measuring multiphase supply currents.

In some embodiments, the motor system 10 includes a motor controller 100 that employs FOC techniques for controlling a motor 104. The motor controller 100 comprises a microcontroller unit 102 executing instructions to implement motor control functionality. The goal of the motor controller 100 is to achieve smooth operation from zero speed to maximum speed of the motor 104 even at different and unknown time-varying disturbances. Using a permanent magnet synchronous motor (PMSM) motor as an example, the motor controller 100 uses continuous-time voltage equations of the PMSM in the d-q coordinate system (where the d-axis is aligned with the magnetic axis of the motor permanent magnets, and the q-axis is perpendicular to the d-axis).

The three-phase sinusoidal currents I_{U}, I_{V}, and I_{W} of the motor stator windings are separated by 120° and generate three non-rotating, pulsating magnetic fields in the U, V, and W directions, respectively, resulting in a rotating magnetic field (stator flux space vector). Vector addition of I_{U}, I_{V}, and I_{W} gives a current space vector. The magnitude of the current space vector may be scaled up or down with no change of direction for a motor rotating at speed, w.

The motor controller 100 comprises a pulse width modulation (PWM) unit 106 128 to generate PWM outputs signals, e.g.: INHA, INLA, INHB, INLB, INHC, and INLC, in FIG. 1A to drive an inverter 108 through a gate driver 110. The output signals of the inverter 108 drive the phases of the motor 104. In some embodiments, the inverter 108 comprises a three-phase two-level voltage inverter including high side switches HS_U, HS_V, HS_W and low side switches LS_U, LS_V, LS_W.

A current sense unit 112 senses phase currents of the motor 104. In some embodiments, as illustrated in FIG. 1A, the current sense unit 112 comprises three shunt resistors 113A, 113B, 113C associated with the three legs of the inverter 108 to sense the current of each phase of the motor 104 by measuring the voltage drop across the shunt resistors. In some embodiments, two shunt resistors are used to sense the current of two phases of the motor 104. The current from the third phase of the motor 104 may be calculated based on the relationship I_{U}+I_{V}+I_{W}=0. In some embodiments, a single shunt resistor is inserted into to a DC link of the inverter 108 to sense a DC link current, and a three-phase current reconstruction is used to obtain the current information for each phase of the motor 104. In some embodiments, sensors such as motor phase in-line shunt resistors, Hall sensors, current transducers (e.g. LEM current sensors), or other motor phase current sensors may be used to obtain the current information for each phase of the motor 104.

An analog-to-digital converter (ADC) 114 receives the sensed currents from the current sense unit 112 to generate digital inputs the motor controller 100 to generate phase current measurement parameters, I_{U}, I_{V}, and I_{W}. The phase current measurements are employed as feedback parameters for the motor controller 100 to update the inphase, D, and quadrature, Q, motor control parameters.

In some embodiments, the phase current waveforms, I_{U}, I_{V}, and I_{W}, are also provided to one or more comparator waveform generators 116, for example, one comparator waveform generator 116 for each motor phase. The comparator waveform generators 116 employ a protection waveform memory 118 for generating a protection waveform for comparison against the motor phase current waveforms to implement real time protection. In some embodiments, the protection waveform memory 118 may be implemented using a lookup table. In some embodiments, the motor controller 100 may implement additional protection functions, but the time delay associated with the ADC 114 and the software protection functionality may be significant. In comparison, the comparator waveform generators 116 operate on the analog phase current measurements to implement a reduced latency protection function. In some embodiments, the comparator waveform generators 116 employ analog comparators that compare the analog phase current waveforms to the protection waveform from the protection waveform memory 118 in near real time.

Some of the disclosed techniques may be readily implemented in software using object or object-oriented software development environments that provide portable source code that can be used on a variety of computer or workstation platforms. Alternatively, the disclosed techniques and/or arrangements may be implemented partially or fully in using standard logic circuits or VLSI design. In some embodiments, the motor 104, the inverter 108, the current sense unit 112, and the ADC 114 are hardware-implemented and PWM 106 is software implemented under the control of the MCU 102. In some embodiments, motor controller 100 is implemented using Programmable System-on-a-Chip (PSoC®) hardware with programmable analog sub blocks that may be configured to implement the comparator waveform generators 116 independently from the MCU 102. However, other Systems on Chip (SoCs) or other combinations of hardware, firmware, or software are contemplated.

The protection waveform memory 118 may be a subset of the memory of the motor controller 100, such as random access memory (RAM), or the protection waveform memory 118 may be external to the motor controller 100. In some embodiments, the protection waveform memory 118 and the comparator waveform generators 116 are configured during the initialization of the motor system 10 under the control of firmware. The values of the protection waveform may be loaded into the protection waveform memory 118 from a non-volatile memory. Parameters for accessing the protection waveform memory 118, such as start address, end address, step size, step direction, or update period, may be loaded into the comparator waveform generators 116 during the initialization. Multiple sets of access parameters may be provided for different trigger events, such as motor startup, motor operation, or motor shutdown. The protection waveform memory 118 may store multiple protection waveforms, each associated with a different trigger event.

In some embodiments, the protection waveform may be symmetrical, such as in the case of a periodic signal. For example, a rising portion of the protection waveform may match the falling portion of the protection waveform other than the direction. In such cases, only the rising portion of the protection waveform may be stored in the protection waveform memory 118. The rising portion of the protection waveform may be accessed in the protection waveform memory 118 based on a starting address, an ending address and a forward step size. The falling portion of the protection waveform generated using the rising portion of the protection waveform in the protection waveform memory 118 by reversing the starting address and the ending address and using a negative step direction. The frequency of a periodic protection waveform or the ramp rate of a linear protection waveform may be changed by modifying the step size, wherein an increased frequency or ramp rate corresponds to an increased step size. Providing flexible addressing for the protection waveform memory 118 allows a much smaller protection waveform memory 118 to support a variety of protection waveforms.

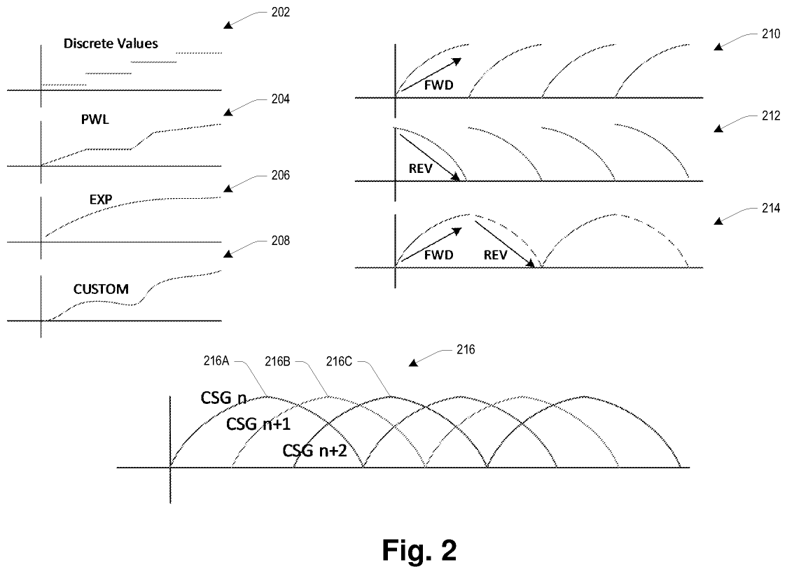

FIG. 2 is a diagram 200 illustrating example protection waveforms that may be stored in the protection waveform memory 118. In some embodiments, the protection waveform may be a discrete function as illustrated by the waveform 202, a piecewise linear function as illustrated by the waveform 204, an exponential waveform as illustrated by the waveform 206, or a custom waveform as illustrated by the waveform 208.

In some embodiments, a composite protection waveform may be generated by cycling through the protection waveform memory 118 in different manners. The waveform 210 illustrates a protection waveform that repeats periodically. The waveform 210 may be generated by stepping through the same region of the protection waveform memory 118 multiple times in a forward direction. A converse waveform 212 may be generated by stepping through the same region of the protection waveform memory 118 multiple times in a reverse direction. A composite waveform 214 may be generated by stepping through a region of the protection waveform memory 118 in a forward direction and then stepping through the same region of the protection waveform memory 118 in a reverse direction. The forward and reverse steps may be repeated. A multiphase waveform 216 may be generated configuring multiple comparator waveform generators 116 with different starting address. Consider a protection waveform memory 118 having 900 entries. A first comparator waveform generator 116 is configured to start at address 1 to generate the curve 216A for phase 1 of a three phase system (e.g., motor current). A second comparator waveform generator 116 is configured to start at address 301 to generate the curve 216B for phase 2. A third comparator waveform generator 116 is configured to start at address 601 to generate the curve 216C for phase 3. The protection waveform memory 118 may include the full cycle, or the protection waveform memory 118 may store a half cycle and the protection waveform memory 118 can be accessed in the forward direction for the first half cycle and in the reverse direction for the second half cycle, as illustrated by the waveform 214.

Moreover, the disclosed procedures may be readily implemented in software that can be stored on a computer-readable storage medium (such as a memory storage device), executed on programmed general-purpose computer with the cooperation of a controller and memory, a special purpose computer, a microprocessor, or the like. In these instances, the arrangements and procedures of the described implementations may be implemented as program embedded on personal computer such as an applet, JAVA® or CGI script, as a resource residing on a server or computer workstation, as a routine embedded in a dedicated communication arrangement or arrangement component, or the like. The arrangements may also be implemented by physically incorporating the arrangements and/or procedures into a software and/or hardware system, such as the hardware and software systems of a test/modeling device.

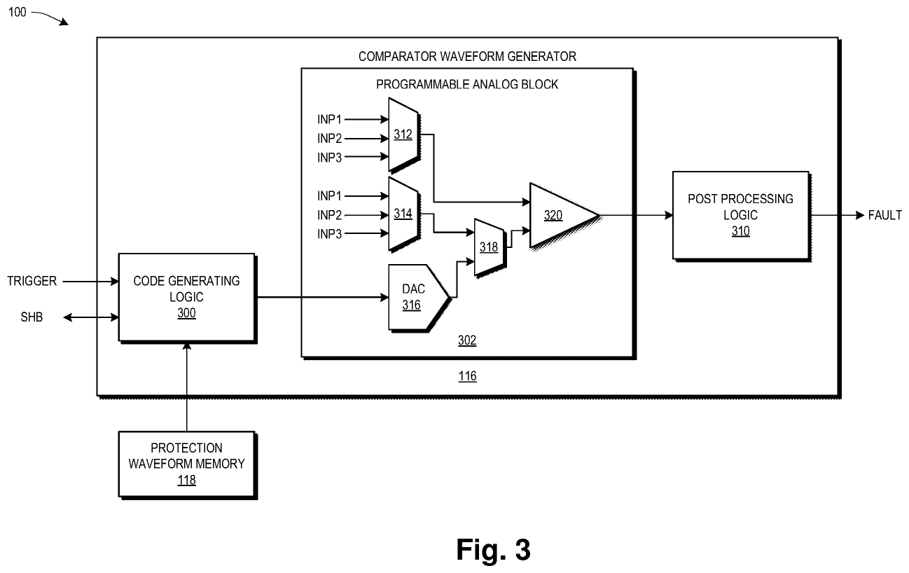

FIG. 3 is a diagram of a comparator waveform generator 116 employing the protection waveform memory 118, according to some embodiments. In some embodiments, the comparator waveform generator 116 comprises code generating logic 300, a programmable analog block 302, and post-processing logic 310. The code generating logic 300 is programmed during initialization to define the addressing scheme for accessing the protection waveform memory 118 to generate the protection waveform. The programmable analog block 302 is programmed during initialization to define the external inputs (e.g., measured phase currents) to compare to the protection waveform. The post-processing logic 310 is programmed during initialization to define the filtering conditions for the output of the programmable analog block 302. For example, to reduce noise in the processed signal, the post-processing logic 310 may determine persistence requirements for the fault condition, where the fault condition needs to be detected for a minimum time period, e.g., three consecutive detections, prior to the post-processing logic 310 generating a fault event. The post-processing logic 310 may implement other noise filtering and stabilizing techniques, such as hysteresis.

In some embodiments, the programmable analog block 302 comprises input multiplexers 312, 314, a digital-to-analog converter (DAC) 316, a routing multiplexer 318, and a comparator 320. The input multiplexers 312, 314 provide flexibility in selecting the inputs to be evaluated. The number of inputs provided to the input multiplexers 312, 314 may vary. In the illustrated embodiment, each input multiplexer 312, 314 can be configured to select one of three inputs INP1, INP2, INP3. The inputs INP1, INP2, INP3 may be external input terminals, such as terminals connected to receive phase current measurement waveforms, or the outputs of other programmable analog blocks 302. The input multiplexer 312 is configured to selects one of the inputs INP1, INP2, INP3 as a first input to the comparator 320. The routing multiplexer 318 is configured to select the output of the DAC 316 or the output of the input multiplexer 314 as a second input to the comparator 320.

The illustration of the programmable analog block 302 is simplified. In some embodiments, additional multiplexers may be provided such that any input, such as an external input, the output of another programmable analog block 302, or the output of the DAC 316 may be provided to either input of the comparator 320. For example, if the protection waveform represents a maximum value, the output of the DAC 316 may be provided at the inverting terminal of the comparator 320 and the external input may be provided to the non-inverting terminal, such that the comparator 320 outputs a logic “0” if the external input is less than the protection waveform and a logic “1” if the external input exceeds the protection waveform. Conversely, if the protection waveform represents a minimum value, the output of the DAC 316 may be provided at the non-inverting terminal of the comparator 320 and the external input may be provided to the inverting terminal, such that the comparator 320 outputs a logic “0” if the external input is greater than the protection waveform and a logic “1” if the external input falls below the protection waveform.

The code generating logic 300 is programmed during initialization with various trigger events. Each trigger event may have an associated protection waveform generated as described in reference to FIG. 2. For each trigger event, a set of access parameters, such as starting address, ending address, step direction, step size, or update period is defined for accessing the protection waveform memory 118 to generate the protection waveform. Example trigger events include a rising or falling edge of a PWM signal from the PWM 106, a startup event, a shutdown event, a user defined event, a monitoring event (e.g., an event identified by the MCU 102), a trigger event identified by a different comparator waveform generator 116 or some other trigger event.

During operation, the code generating logic 300 receives a trigger event and uses the access parameters for the trigger event to access the protection waveform memory 118 to generate a protection waveform. The DAC 316 receives the protection waveform and generates an analog protection waveform signal. The input selected by the input multiplexer 312 is compared to the analog protection waveform signal from the DAC 316 in the comparator 320. In some embodiments, the comparator 320 outputs a logic zero if the input does not exceed the protection waveform and outputs a logic one if the input exceeds the protection waveform.

In a motor control example, the inputs INP1, INP2, INP3 may be the phase currents. The input multiplexer 312 is configured to select one of the measured phase currents. The multiplexer 318 is configured to connect the DAC 316 to the comparator 320. The code generating logic 300 is configured to access the protection waveform memory 118 to generate the protection waveform for the corresponding phase selected for the comparator waveform generator 116 to monitor. In the case of a maximum threshold, the comparator generates a logic “1” during operation if the measured phase waveform exceeds the protection waveform.

The processing logic 310 generates a fault event if persistence requirements are met. The fault event may trigger a direct hardware protective action such as terminating the PWM signal generated by the PWM 106 to shut down the motor 104, slowing down the motor, or reducing motor torque. In some embodiments, the fault event may include a fault interrupt provided to the MCU 102 for processing. The MCU 102 may take various protective actions, such as sending alert messages or reports oy by implementing protective actions similar to the hardware protective actions including slowing down the motor, reducing motor torque, or stopping the motor 104. Note that the detection of the fault event and the implementing of a protective action in the case of a direct hardware intervention are managed in hardware by the comparator waveform generator 116 without placing any processing burden on the MCU 102.

In some embodiments, different comparator waveform generators 116 may be provided for monitoring different measured system characteristics, such as different motor phase currents, or different comparator waveform generators 116 may be provided for monitoring the same measured system characteristic, but with a different threshold. For example, a warning fault event may be generated using a first protection waveform from the protection waveform memory 118 by a first comparator waveform generator 116, and a shutdown fault event may be generated using a second protection waveform from the protection waveform memory 118 by a second comparator waveform generator 116.

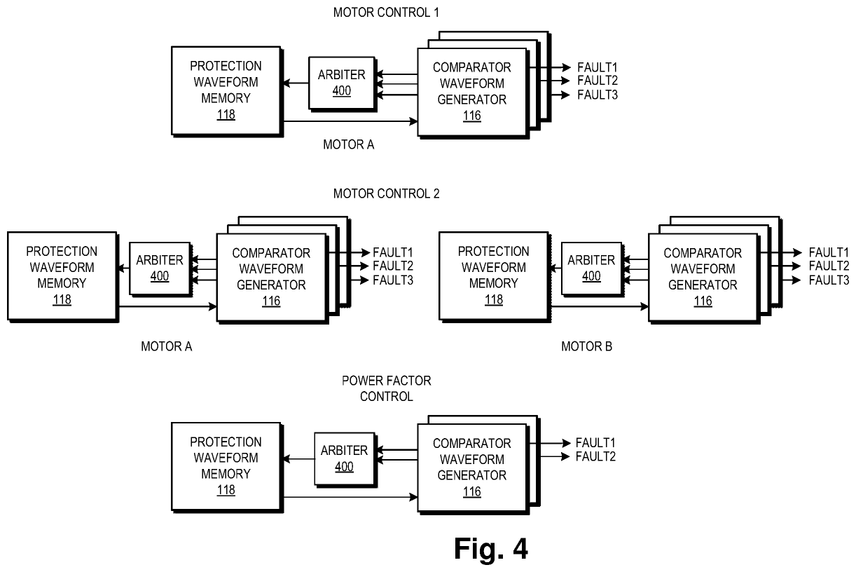

FIG. 4 is a diagram illustrating multiple comparator waveform generators 116 with a shared protection waveform memory 118, according to some embodiments. In embodiments where the protection waveform memory 118 is shared, an arbiter 400 is provided to prevent concurrent accesses to the protection waveform memory 118. The arbiter 400 pauses an access request while another access is occurring and releases the access request after the access competes.

Referring to FIG. 4, for monitoring a first motor, (MOTOR CONTROL 1), three comparator waveform generators 116 are provided, one for each phase. Each of the comparator waveform generators 116 is programmed to monitor a different phase using a protection waveform specific to the monitored phase, for example, as illustrated in FIG. 2 by the waveform 216. The arbiter 400 allows the multiple comparator waveform generators 116 to share the protection waveform memory 118 without access conflicts.

In a case where the motor controller 100 controls multiple motors, a second motor may be monitored (MOTOR CONTROL 2), using another set of three comparator waveform generators 116, one for each phase. Again, each of the comparator waveform generators 116 is programmed to monitor a different phase using a protection waveform specific to the monitored phase, for example, as illustrated in FIG. 2 by the waveform 216. The arbiter 400 allows the multiple comparator waveform generators 116 to share the protection waveform memory 118 without access conflicts.

In some cases, the power supply for powering the motors 104 may be generated by a power supply inverter that converts a supply voltage, such as an external AC line voltage to a DC voltage (e.g., V_{DC} in FIG. 1). Power factor control may be provided for the power supply inverter to reduce reactive power consumption relative to real power consumption to bring the power factor closer to “1”. The power factor controller may be monitored for fault conditions (POWER FACTOR CONTROL), using two comparator waveform generators 116, one for AC current and one for AC voltage, for example. Each of the comparator waveform generators 116 is programmed to monitor the power factor controller according to a protection waveform specific to the monitored AC voltage or AC current. The arbiter 400 allows the multiple comparator waveform generators 116 to share the protection waveform memory 118 without access conflicts.

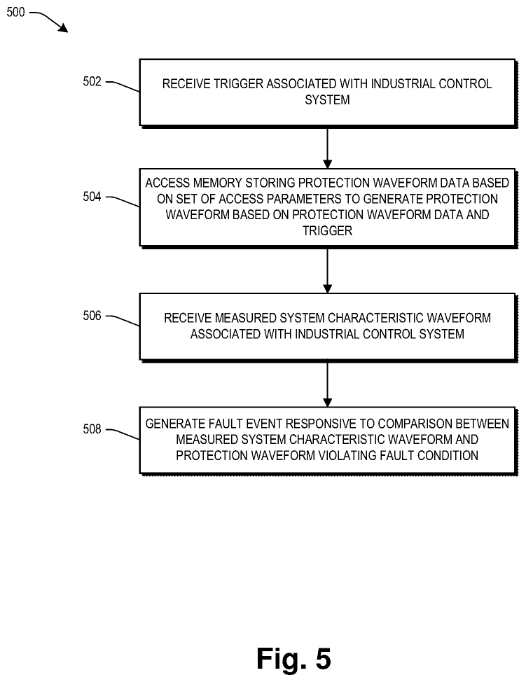

FIG. 5 is a simplified flow diagram of a method 500 for implementing industrial control protection, according to some embodiments. At 502, a trigger associated with an industrial control system is received. In some embodiments, the trigger is a startup event, a shutdown event, a run event, or some other type of event having a unique protection profile. At 504, a memory storing protection waveform data is accessed on a set of access parameters to generate a protection waveform based on the protection waveform data and the trigger. At 506, measured system characteristic waveform associated with the industrial control system is received. At 508, a fault event is generated responsive to a comparison between the measured system characteristic waveform and the protection waveform violating a fault condition.

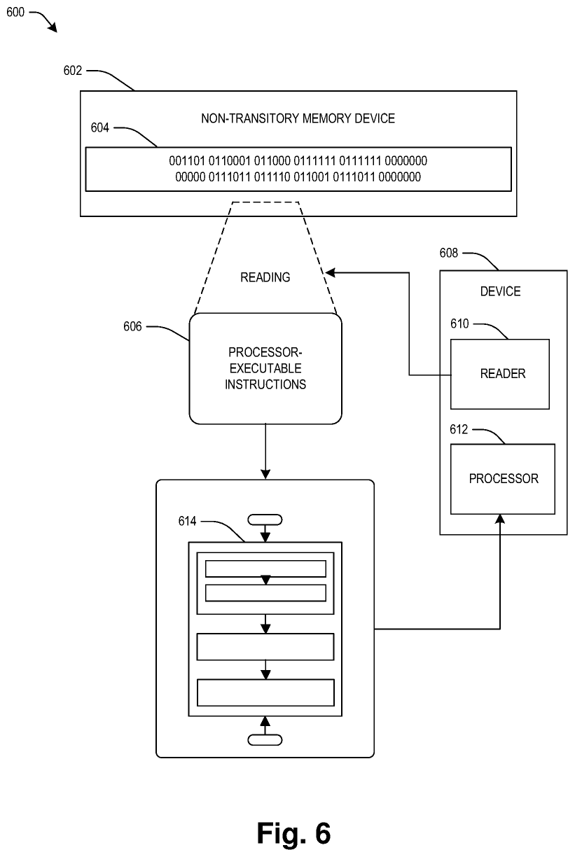

FIG. 6 illustrates an exemplary embodiment 600 of a computer-readable medium 602, according to some embodiments. One or more embodiments involve a computer-readable medium comprising processor-executable instructions configured to implement one or more of the techniques presented herein. The embodiment 600 comprises a non-transitory computer-readable medium 602 (e.g., a CD-R, DVD-R, flash drive, a platter of a hard disk drive, etc.), on which is encoded computer-readable data 604. This computer-readable data 604 in turn comprises a set of processor-executable computer instructions 606 that, when executed by a computing device 608 including a reader 610 for reading the processor-executable computer instructions 606 and a processor 612 for executing the processor-executable computer instructions 606, are configured to facilitate operations according to one or more of the principles set forth herein. In some embodiments, the processor-executable computer instructions 606, when executed, are configured to facilitate performance of a method 614, such as at least some of the aforementioned method(s). In some embodiments, the processor-executable computer instructions 606, when executed, are configured to facilitate implementation of a system, such as at least some of the one or more aforementioned system(s). Many such computer-readable media may be devised by those of ordinary skill in the art that are configured to operate in accordance with the techniques presented herein.

The term “computer readable media” may include communication media. Communication media typically embodies computer readable instructions or other data in a “modulated data signal” such as a carrier wafer or other transport mechanism and includes any information delivery media. The term “modulated data signal” may include a signal that has one or more of its characteristics set or changed in such a manner as to encode information in the signal.

According to some embodiments, a system comprises a memory configured to store protection waveform data, and a comparator waveform generator configured to access the memory to generate a protection waveform from the protection waveform data based on a trigger associated with the system, receive a measured system characteristic waveform, and generate a fault interrupt responsive to a comparison between the measured system characteristic waveform and the protection waveform violating a fault condition.

According to some embodiments, the fault condition comprises the measured system characteristic waveform exceeding the protection waveform.

According to some embodiments, the memory comprises a protection waveform lookup table, the comparator waveform generator is configured to access the protection waveform lookup table based on a set of access parameters to generate the protection waveform based on the protection waveform data, and the set of access parameters comprises at least one of a start address, an end address, a step size, a step direction, or an update period.

According to some embodiments, the comparator waveform generator comprises code generation logic configured to access the memory based on a set of access parameters to generate the protection waveform, a programmable analog block comprising a multiplexer configured to select an input terminal for receiving the measured system characteristic waveform, a digital-to-analog converter connected to the code generation logic and configured to convert the protection waveform to an analog protection waveform, and a comparator configured to compare the analog protection waveform to the measured system characteristic waveform to identify the fault condition.

According to some embodiments, the comparator waveform generator comprises post processing logic connected to the comparator and configured to generate the fault interrupt responsive to the fault condition being violated for a predetermined time period.

According to some embodiments, the code generation logic is configured to generate the protection waveform by accessing the memory in a forward direction for generating a first portion of the protection waveform and by accessing the memory in a reverse direction for generating a second portion of the protection waveform.

According to some embodiments, the set of access parameters comprises a first subset associated with a first trigger and a second subset associated with a second trigger, and the code generation logic is configured to receive a trigger event and access the memory to generate the protection waveform using the first subset responsive to the trigger event corresponding to the first trigger or access the memory to generate the protection waveform using the second subset responsive to the trigger event corresponding to the second trigger.

According to some embodiments, the system comprises a second comparator waveform generator configured to access the memory to generate a second protection waveform based on the protection waveform data, receive a second measured system characteristic waveform, and generate a second fault interrupt responsive to a comparison between the second measured system characteristic waveform and the second protection waveform violating a second fault condition, and an arbiter configured to manage one or more requests from at least one of the comparator waveform generator or the second comparator waveform generator to access the memory.

According to some embodiments, an industrial controller comprises a controller implemented by a microcontroller and configured to control an industrial process, a memory configured to store protection waveform data, and a comparator waveform generator configured to access the memory based on a set of access parameters to generate a protection waveform based on the protection waveform data and a trigger event, receive a measured system characteristic waveform associated with an industrial system controlled by the controller and associated with the industrial process, and generate a fault interrupt for the microcontroller responsive to a comparison between the measured system characteristic waveform and the protection waveform violating a fault condition.

According to some embodiments, the controller comprises a motor controller, and the measured system characteristic waveform comprises a representation of motor phase current.

According to some embodiments, the memory comprises a protection waveform lookup table, and the set of access parameters comprises at least one of a start address, an end address, a step size, a step direction, or an update period for accessing the protection waveform lookup table.

According to some embodiments, the comparator waveform generator comprises code generation logic configured to store the set of access parameters and access the memory based on the set of access parameters to generate the protection waveform, and a programmable analog block comprising a multiplexer configured to select an input terminal for receiving the measured system characteristic waveform, a digital-to-analog converter connected to the code generation logic and configured to convert the protection waveform to an analog protection waveform, and a comparator configured to compare the analog protection waveform to the measured system characteristic waveform to identify the fault condition.

According to some embodiments, the code generation logic is configured to generate the protection waveform by accessing the memory in a forward direction for generating a first portion of the protection waveform and by accessing the memory in a reverse direction for generating a second portion of the protection waveform.

According to some embodiments, the set of access parameters comprises a first subset associated with a first trigger and a second subset associated with a second trigger, and the code generation logic is configured to receive the trigger and access the memory to generate the protection waveform using the first subset responsive to the trigger corresponding to the first trigger or access the memory to generate the protection waveform using the second subset responsive to the trigger corresponding to the second trigger.

According to some embodiments, a method comprises receiving a trigger associated with an industrial control system, accessing a memory storing protection waveform data based on a set of access parameters to generate a protection waveform based on the protection waveform data and the trigger, receiving a measured system characteristic waveform associated with the industrial control system, and generating a fault interrupt responsive to a comparison between the measured system characteristic waveform and the protection waveform violating a fault condition.

According to some embodiments, the memory comprises a protection waveform lookup table, and accessing the memory based on the set of access parameters comprises accessing the protection waveform lookup table based on at least one of a start address, an end address, a step size, a step direction, or an update period.

According to some embodiments, the method comprises configuring a multiplexer to select an input terminal for receiving the measured system characteristic waveform, configuring a digital-to-analog converter to convert the protection waveform to an analog protection waveform, and configuring a comparator to compare the analog protection waveform to the measured system characteristic waveform to identify the fault condition.

According to some embodiments, accessing the memory based on the set of access parameters comprises accessing the memory in a forward direction for generating a first portion of the protection waveform, and accessing the memory in a reverse direction for generating a second portion of the protection waveform.

According to some embodiments, the set of access parameters comprises a first subset associated with a first trigger and a second subset associated with a second trigger, and the method comprises accessing the memory to generate the protection waveform using the first subset responsive to the trigger corresponding to the first trigger or accessing the memory to generate the protection waveform using the second subset responsive to the trigger corresponding to the second trigger.

According to some embodiments, the method comprises accessing the memory based on a second set of access parameters to generate a second protection waveform as a function of the protection waveform data, receiving a second measured system characteristic waveform, and generating a second fault interrupt responsive to a comparison between the second measured system characteristic waveform and the second protection waveform violating a second fault condition.

Various operations of embodiments are provided herein. In an embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering may be implemented without departing from the scope of the disclosure. Further, it will be understood that not all operations are necessarily present in each embodiment provided herein. Also, it will be understood that not all operations are necessary in some embodiments.

Any aspect or design described herein as an “example” and/or the like is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. A system, comprising:
a memory configured to store protection waveform data; and
a comparator waveform generator configured to access the memory to generate a protection waveform from the protection waveform data based on a trigger associated with the system, receive a measured system characteristic waveform, and generate a fault interrupt responsive to a comparison between the measured system characteristic waveform and the protection waveform violating a fault condition.

2. The system of claim 1, wherein the fault condition comprises the measured system characteristic waveform exceeding the protection waveform.

3. The system of claim 1, wherein:
the memory comprises a protection waveform lookup table;
the comparator waveform generator is configured to access the protection waveform lookup table based on a set of access parameters to generate the protection waveform based on the protection waveform data; and
the set of access parameters comprises at least one of a start address, an end address, a step size, a step direction, or an update period.

4. The system of claim 1, wherein the comparator waveform generator comprises:
code generation logic configured to access the memory based on a set of access parameters to generate the protection waveform;
a programmable analog block comprising:
a multiplexer configured to select an input terminal for receiving the measured system characteristic waveform;
a digital-to-analog converter connected to the code generation logic and configured to convert the protection waveform to an analog protection waveform; and
a comparator configured to compare the analog protection waveform to the measured system characteristic waveform to identify the fault condition.

5. The system of claim 4, wherein the comparator waveform generator comprises:
post processing logic connected to the comparator and configured to generate the fault interrupt responsive to the fault condition being violated for a predetermined time period.

6. The system of claim 4, wherein:
the code generation logic is configured to generate the protection waveform by accessing the memory in a forward direction for generating a first portion of the protection waveform and by accessing the memory in a reverse direction for generating a second portion of the protection waveform.

7. The system of claim 4, wherein:
the set of access parameters comprises a first subset associated with a first trigger and a second subset associated with a second trigger; and
the code generation logic is configured to receive a trigger event and access the memory to generate the protection waveform using the first subset responsive to the trigger event corresponding to the first trigger or access the memory to generate the protection waveform using the second subset responsive to the trigger event corresponding to the second trigger.

8. The system of claim 1, comprising:
a second comparator waveform generator configured to access the memory to generate a second protection waveform based on the protection waveform data, receive a second measured system characteristic waveform, and generate a second fault interrupt responsive to a comparison between the second measured system characteristic waveform and the second protection waveform violating a second fault condition; and
an arbiter configured to manage one or more requests from at least one of the comparator waveform generator or the second comparator waveform generator to access the memory.

9. An industrial controller, comprising:
a controller implemented by a microcontroller and configured to control an industrial process;
a memory configured to store protection waveform data; and
a comparator waveform generator configured to access the memory based on a set of access parameters to generate a protection waveform based on the protection waveform data and a trigger event, receive a measured system characteristic waveform associated with an industrial system controlled by the controller and associated with the industrial process, and generate a fault interrupt for the microcontroller responsive to a comparison between the measured system characteristic waveform and the protection waveform violating a fault condition.

10. The industrial controller of claim 9, wherein:
the controller comprises a motor controller; and
the measured system characteristic waveform comprises a representation of motor phase current.

11. The industrial controller of claim 9, wherein:
the memory comprises a protection waveform lookup table; and
the set of access parameters comprises at least one of a start address, an end address, a step size, a step direction, or an update period for accessing the protection waveform lookup table.

12. The industrial controller of claim 9, wherein the comparator waveform generator comprises:
code generation logic configured to store the set of access parameters and access the memory based on the set of access parameters to generate the protection waveform; and
a programmable analog block comprising:
a multiplexer configured to select an input terminal for receiving the measured system characteristic waveform;
a digital-to-analog converter connected to the code generation logic and configured to convert the protection waveform to an analog protection waveform; and
a comparator configured to compare the analog protection waveform to the measured system characteristic waveform to identify the fault condition.

13. The industrial controller of claim 12, wherein:
the code generation logic is configured to generate the protection waveform by accessing the memory in a forward direction for generating a first portion of the protection waveform and by accessing the memory in a reverse direction for generating a second portion of the protection waveform.

14. The industrial controller of claim 12, wherein:
the set of access parameters comprises a first subset associated with a first trigger and a second subset associated with a second trigger; and
the code generation logic is configured to receive the trigger and access the memory to generate the protection waveform using the first subset responsive to the trigger corresponding to the first trigger or access the memory to generate the protection waveform using the second subset responsive to the trigger corresponding to the second trigger.

15. A method, comprising:
receiving a trigger associated with an industrial control system;
accessing a memory storing protection waveform data based on a set of access parameters to generate a protection waveform based on the protection waveform data and the trigger;
receiving a measured system characteristic waveform associated with the industrial control system; and
generating a fault interrupt responsive to a comparison between the measured system characteristic waveform and the protection waveform violating a fault condition.

16. The method of claim 15, wherein:
the memory comprises a protection waveform lookup table; and
accessing the memory based on the set of access parameters comprises:
accessing the protection waveform lookup table based on at least one of a start address, an end address, a step size, a step direction, or an update period.

17. The method of claim 15, comprising:
configuring a multiplexer to select an input terminal for receiving the measured system characteristic waveform;
configuring a digital-to-analog converter to convert the protection waveform to an analog protection waveform; and
configuring a comparator to compare the analog protection waveform to the measured system characteristic waveform to identify the fault condition.

18. The method of claim 15, wherein accessing the memory based on the set of access parameters comprises:
accessing the memory in a forward direction for generating a first portion of the protection waveform; and
accessing the memory in a reverse direction for generating a second portion of the protection waveform.

19. The method of claim 15, wherein:
the set of access parameters comprises a first subset associated with a first trigger and a second subset associated with a second trigger; and
the method comprises:
accessing the memory to generate the protection waveform using the first subset responsive to the trigger corresponding to the first trigger or accessing the memory to generate the protection waveform using the second subset responsive to the trigger corresponding to the second trigger.

20. The method of claim 15, comprising:
accessing the memory based on a second set of access parameters to generate a second protection waveform as a function of the protection waveform data;
receiving a second measured system characteristic waveform; and
generating a second fault interrupt responsive to a comparison between the second measured system characteristic waveform and the second protection waveform violating a second fault condition.
